(19) United States
(12) Patent Application Publication
(10) Pub. No.: US 2010/0258155 A1
(43) Pub. Date: Oct. 14, 2010

(54) THERMOELECTRIC ELEMENT

(75) Inventors: Sung Ho LEE, Seongnam (KR); Yongsoo OH, Seongnam (KR); Chan Yeup CHUNG, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/547,000

(22) Filed: Aug. 25, 2009

(30) Foreign Application Priority Data
Apr. 13, 2009 (KR) 10-2009-0031784

(51) Int. Cl. H01L 35/28

(52) U.S. Cl. 136/203

(57) ABSTRACT

There is provided a thermoelectric (TE) element. The TE element includes a plurality of pn junctions each formed by bonding an n-type TE semiconductor and a p-type TE semiconductor with a metallic layer interposed therebetween, and a first electrode and a second electrode electrically connected to the n-type TE semiconductor and the p-type TE semiconductor, respectively. The plurality of pn junctions are laminated with insulating layers interposed therebetween, and are connected electrically in parallel to each other. Even in the case that a section of components does not operate electrically, the operation of the entire element is not adversely affected, thereby improving stability of the TE element.

### CROSS-REFERENCE TO RELATED APPLICATIONS

This application claims the priority of Korean Patent Application No. 2009-0031784 filed on Apr. 13, 2009, in the Korean Intellectual Property Office, the disclosure of which is incorporated herein by reference.

### BACKGROUND OF THE INVENTION

1. Field of the Invention

The present invention relates to a thermoelectric element having improved stability and thermoelectric efficiency.

2. Description of the Related Art

Due to rapid increase in the use of fossil fuel energy, there are concerns about global warming and the exhaustion of existing energy supplies. This has stimulated interest in the thermoelectric (TE) element. The TE element is used as a cooling device substitute for freon gas or the like which contribute to air pollution. Also, it is used extensively as a small generator utilizing the Seebeck effect. Particularly, when a loop is formed by which metals are grounded to each other by the medium of a semiconductor (a TE semiconductor) and a current is passed through the loop, a potential difference is generated by a Fermi energy difference. At this time, electrons take energy necessary to move from one metal surface to another metal surface, resulting in a cooling effect (heat absorption). In contrast, energy equivalent to the energy the electrons bring is taken out in another metal surface, resulting in a heating effect (heat emission). This is the so called Peltier effect, which is a principle of operating a cooling device by the use of the TE element. Here, a position of the heat absorption and the heat emission is determined based on types of semiconductor and directions of current flow, and variations in semiconductor materials lead to different effects.

FIG. 1 is a schematic cross-sectional view illustrating the general structure of a TE element. In a typical TE element 10, an n-type TE semiconductor 11 and a p-type TE semiconductor 12 are electrically connected by a metallic layer 15. If a direct current is passed therethrough, heat absorption occurs on a heat absorbing layer 13 and heat emission occurs on a heat emitting layer 14. In this case, as described above, the respective positions of heat absorption and heat emission may be changeable according to the direction of current flow. Each of the n-type and p-type TE semiconductors 11 and 12 is provided in plurality. The plurality of n-type and p-type TE semiconductors 11 and 12 are alternately arranged and electrically connected in series. In that series connection, if there is a problem with one of TE semiconductors or metallic layers, the entire element may not operate in an optimal manner.

### SUMMARY OF THE INVENTION

An aspect of the present invention provides a thermoelectric (TE) element having improved stability and thermoelectric efficiency in that even in the case that a section of components does not operate electrically, the operation of the entire element is not adversely affected.

According to an aspect of the present invention, there is provided a TE element including a plurality of pn junctions each formed by bonding an n-type TE semiconductor and a p-type TE semiconductor with a metallic layer interposed therebetween, and a first electrode and a second electrode electrically connected to the n-type TE semiconductor and the p-type TE semiconductor, respectively. The plurality of pn junctions are laminated with insulating layers interposed therebetween, and are connected electrically in parallel to each other.

The n-type and p-type TE semiconductors of at least one of the plurality of pn junctions may be formed of materials having thermal conductivity different from that of another pn junction.

In this case, the thermal conductivity in the materials of the n-type and p-type TE semiconductors may increase from an upper part to a lower part with respect to the lamination direction of the plurality of pn junctions.

The lamination direction of the plurality of pn junctions may be identical to the direction of heat flow in the TE element.

The metallic layer may be formed of the same material as the first and second electrodes.

The first electrode may be a common electrode for the n-type TE semiconductor in each of the plurality of pn junctions.

The second electrode may be a common electrode for the p-type TE semiconductor in each of the plurality of pn junctions.

The first and second electrodes may be arranged in a lateral direction of a structure including the plurality of pn junctions.

In this case, the first and second electrodes may be arranged to face each other.

The n-type and p-type TE semiconductors may contact the first and second electrodes, respectively, and be arranged to be spaced apart from the second and first electrodes, respectively.

In this case, the TE element may further include insulating materials that are formed between the n-type TE semiconductor and the second electrode and between the p-type TE semiconductor and the first electrode, respectively.

The TE element may further include a ceramic layer and a heat absorbing layer successively formed on an upper surface of a pn junction positioned at the top of the plurality of pn junctions with respect to the lamination direction of the plurality of pn junctions.

In this case, a ceramic material included in the ceramic layer may be alumina.

The TE element may further include a heat sink formed on a lower surface of a pn junction positioned at the bottom of the plurality of pn junctions with respect to the lamination direction of the plurality of pn junctions.

The TE element may further include a power source connected to the first and second electrodes to form a circuit. The power source allows current to flow through the plurality of pn junctions so that heat absorbed from one side of the plurality of pn junctions is transferred along the lamination direction of the plurality of pn junctions.

The TE element may further include a resistance device connected to the first and second electrodes to form a circuit. In this case, current may flow through the plurality of pn junctions and the resistance device by heat absorbed from one side of the plurality of pn junctions.

The insulating layers may be formed of a ceramic material.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view illustrating a general structure of a thermoelectric (TE) element;

FIG. 2 is a schematic cross-sectional view illustrating a TE element according to an exemplary embodiment of the present invention;

FIG. 3 is a schematic view illustrating a parallel connection structure of pn junctions in the exemplary embodiment of FIG. 2;

FIG. 4 is a schematic view illustrating an example of using the TE of FIG. 1 as a TE cooler;

FIG. 5 is a schematic view illustrating an example of using the TE of FIG. 1 as a TE generator; and

FIG. 6 is a schematic cross-sectional view illustrating pn junctions applied for another embodiment that is modified in the exemplary embodiment of FIG. 2.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

FIG. 2 is a schematic cross-sectional view illustrating a thermoelectric element according to an exemplary embodiment of the present invention. A thermoelectric (TE) element 100 of this embodiment includes: n-type TE semiconductors 101 and p-type TE semiconductors 102 creating pn junctions where metallic layers 103 are interposed between the n-type and p-type TE semiconductors 101 and 102; insulating layers 104 interposed between the pn junctions for a parallel connection of the pn junctions; a first electrode 105 and a second electrode 106; ceramic layers 107 and 109; a heat absorbing layer 108; and a heat sink 110.

The n-type and p-type TE semiconductors 101 and 102 may use materials typically used in this technical field and suitably doped, for example, TE materials such as BiTe-based materials and PbTe-based materials. The metallic layer 103 may use materials having a high electrical conductivity such as copper so that current flows smoothly. The TE element 100 may be used as a TE cooler by allowing for heat transfer from one side to the other side in accordance with current flow that is generated when voltage is applied to the n-type and p-type TE semiconductors 101 and 102. Also, current may be generated by the use of energy that is generated by making the temperature of one side different from that of the other side in a structure having the n-type and p-type TE semiconductors 101 and 102.

The n-type TE semiconductor 101, the metallic layer 103, and the p-type TE semiconductor 102 are involved in a single unit structure performing a TE function, which is hereinafter referred to as a “pn junction”. There are provided a plurality of pn junctions to be laminated. In this embodiment, one pn junction is connected electrically in parallel to another pn junction, which is different from pn junctions that are connected in series according to the related art. FIG. 3 is a schematic view illustrating a parallel connection structure of the pn junctions. Such a parallel connection structure provides an advantage in that even if there are some defects in part of the pn junctions, such defects do not affect the operation of the entire element. For the parallel connection, the insulating layer 104 is interposed between the pn junctions. The insulating layer 104 may be formed of a ceramic material such as alumina.

As described above, the TE element 100 is able to absorb heat at one side and emit the heat to the other side by a structure in which the pn junctions are laminated (hereinafter referred to as “laminate structure”). In the laminate structure, the heat absorbing layer 108 and the heat sink 110 are suitably bonded, thereby being capable of performing the TE function. According to the laminate structure with reference to FIG. 2, the heat absorbing layer 108 is formed on an upper surface of a pn junction positioned at the top of the laminate structure and the heat sink 110 is formed on a lower surface of a pn junction positioned at the bottom of the laminate structure. Also, the first and second electrodes 105 and 106 in contact with the n-type and p-type TE semiconductors 101 and 102 respectively, may be connected to a power source, a resistance device, or the like to form a circuit. In this case, the heat absorbing layer 108 and the heat sink 110 may be formed of metals having a high thermal conductivity, and as illustrated in FIG. 2, they are connected to the laminate structure by the ceramic layers 107 and 109, respectively. The ceramic layers 107 and 109 include materials such as alumina and the like, and since they are not indispensable elements, they may be ruled out according to exemplary embodiments of the present invention.

Also, as described in the exemplary embodiment, the pn junctions are laminated in one direction, thereby inducing heat flow in the lamination direction of the pn junctions. That is, in the case that the n-type and p-type TE semiconductors 101 and 102 are connected to a positive electrode and a negative electrode, respectively, the current flow allows the heat of the heat absorbing layer 108 to pass through the pn junctions and be emitted to the heat sink 110. In this exemplary embodiment, the pn junctions are connected thermally in series and electrically in parallel. This reverses the connection in the TE element according to the related art, in which the pn junctions are connected thermally in parallel and electrically in series.

In the TE element having the laminate structure according to that exemplary embodiment, considering that the heat flow is induced in the lamination direction, the n-type and p-type TE semiconductors 101 and 102 may be formed of different materials according to lamination directions. Specifically, in the case that a pn junction positioned at a high temperature part, relative to a pn junction positioned at a low temperature part, is formed of TE materials for relatively high temperature, for example, relatively low thermal conductive materials, enhanced TE performance can be achieved. That is, with reference to FIG. 2, if the upper part and the lower part are the high temperature part and the low temperature part, respectively, the thermal conductivity of the materials that form the n-type and p-type TE semiconductors 101 and 102 of the pn junctions may increase from the upper part to the lower part.

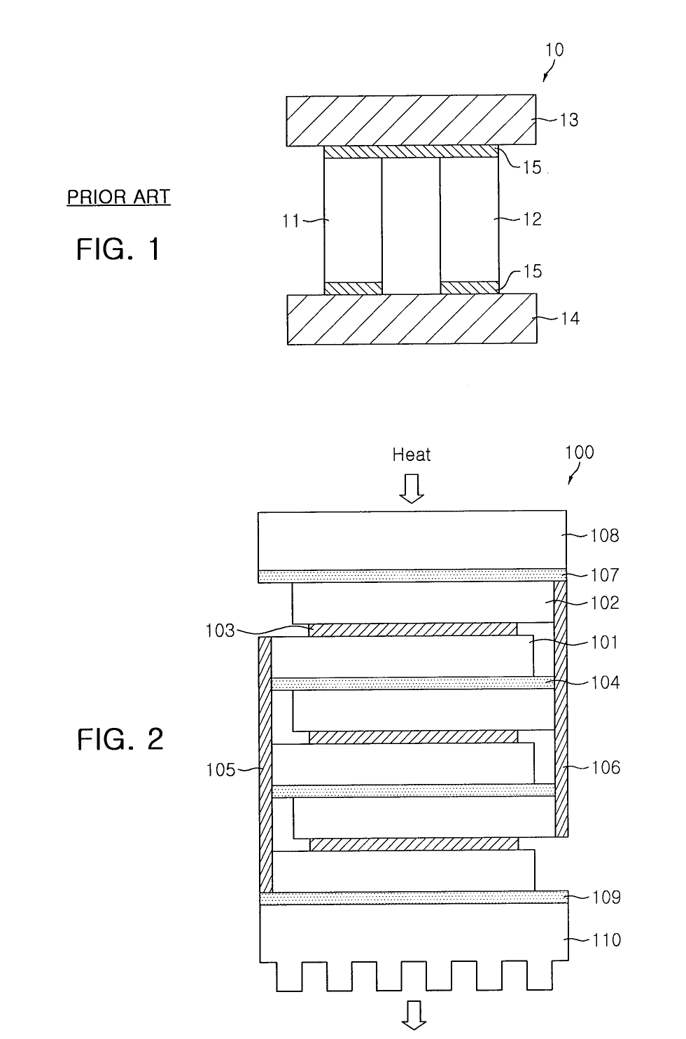

As described above, in the case that the pn junctions are laminated by different thermal conductivity, temperature is distributed to have different temperature gradients from the high temperature part to the low temperature part in the laminate structure. In contrast, the TE element according to the related art shows nearly constant temperature gradients from the high temperature part to the low temperature part. As a result of comparing parallel connection design (laminate structure wherein the pn junctions are laminated by different thermal conductivity) with series connection design (structure illustrated in FIG. 1) in terms of thermal conductivity efficiency by the use of a Finite Element Method (FEM), the thermal conductivity of the parallel connection design is more improved than that of the series connection design. That is, when heat of 100 W/m² is given, the result is that the temperature difference between the high temperature part and the low temperature part is higher by 0.1° C. in the parallel connection design. As demonstrated by this result, electrical stability can be acquired by connecting the pn junctions in parallel and TE efficiency can be improved by laminating the pn junctions along the direction of heat flow and properly selecting the TE materials.

Meanwhile, the first and second electrodes 105 and 106 may contact the n-type and p-type TE semiconductors 101 and 102, respectively, and be formed of the same material as the metallic layer 103. In this case, in order to acquire an efficient contact structure, the first and second electrodes 105 and 106 may be arranged in a lateral direction of the laminate structure of the pn-junctions and face each other. The first electrode 105 and the p-type TE semiconductor 102 are spaced apart from each other, not to contact each other. Likewise, the second electrode 106 and the n-type TE semiconductor 101 are spaced apart from each other, not to contact each other. In this case, as illustrated in FIG. 6, insulating materials 111 may be interposed between the n-type TE semiconductor 101 and the second electrode 106 and between the p-type TE semiconductor 102 and the first electrode 105, respectively.

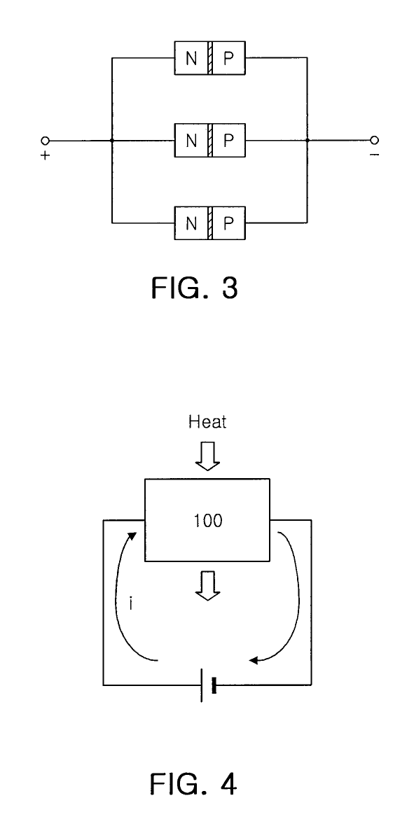

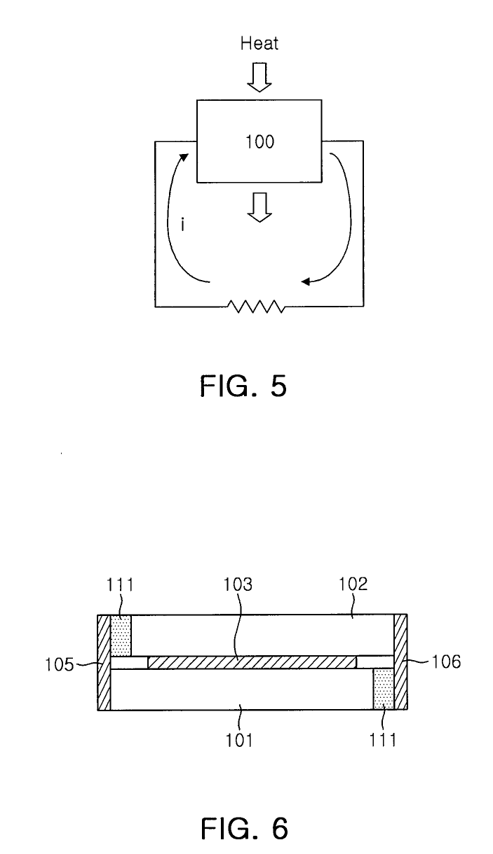

FIG. 4 is a schematic view illustrating an example of using the TE element of FIG. 1 as a TE cooler. Also, FIG. 5 is a schematic view illustrating an example of using the TE element of FIG. 1 as a TE generator. Accordingly, although detailed structures are omitted, the TE element 100 of FIGS. 4 and 5 may be considered to have the same structure as that of FIG. 1. As illustrated in FIG. 4, in the case that the current flow is generated by connecting the TE element 100 to a power source, heat from the upper part (high temperature part) may be emitted to the lower part (low temperature part). In this case, the TE element 100 may be used as a TE cooler and the heat may flow in opposite directions by reversing the polarity of the power source. According to a similar principle, high-temperature thermal energy may generate current, and as seen in the TE generator illustrated in FIG. 5, the heat may be emitted from the high temperature part to the low temperature part by the current.

According to the exemplary embodiments of the present invention, even in the case that a section of components does not operate electrically, the operation of the entire element is not adversely affected, thereby being able to improve stability of the TE element.

Furthermore, the TE element according to the exemplary embodiments of the present invention is able to reduce dependence on the applied voltage and enhance the TE efficiency more than before.

While the present invention has been shown and described in connection with the exemplary embodiments, it will be apparent to those skilled in the art that modifications and variations can be made without departing from the spirit and scope of the invention as defined by the appended claims.

What is claimed is:

1. A thermoelectric (TE) element, comprising:
a plurality of pn junctions each formed by bonding an n-type TE semiconductor and a p-type TE semiconductor with a metallic layer interposed therebetween; and
a first electrode and a second electrode electrically connected to the n-type TE semiconductor and the p-type TE semiconductor, respectively,
wherein the plurality of pn junctions are laminated with insulating layers interposed therebetween, and are connected electrically in parallel to each other.

2. The TE element of claim 1, wherein the n-type and p-type TE semiconductors of at least one of the plurality of pn junctions are formed of materials having thermal conductivity different from that of another pn junction.

3. The TE element of claim 2, wherein thermal conductivity in the materials of the n-type and p-type TE semiconductors increases from an upper part to a lower part with respect to a lamination direction of the plurality of pn junctions.

4. The TE element of claim 1, wherein a lamination direction of the plurality of pn junctions is identical to a direction of heat flow in the TE element.

5. The TE element of claim 1, wherein the metallic layer is formed of the same material as the first and second electrodes.

6. The TE element of claim 1, wherein the first electrode is a common electrode for the n-type TE semiconductor in each of the plurality of pn junctions.

7. The TE element of claim 1, wherein the second electrode is a common electrode for the p-type TE semiconductor in each of the plurality of pn junctions.

8. The TE element of claim 1, wherein the first and second electrodes are arranged in a lateral direction of a structure including the plurality of pn junctions.

9. The TE element of claim 8, wherein the first and second electrodes are arranged to face each other.

10. The TE element of claim 1, wherein the n-type and p-type TE semiconductors contact the first and second electrodes, respectively, and are arranged to be spaced apart from the second and first electrodes, respectively.

11. The TE element of claim 10, further comprising insulating materials formed between the n-type TE semiconductor and the second electrode and between the p-type TE semiconductor and the first electrode, respectively.

12. The TE element of claim 1, further comprising a ceramic layer and a heat absorbing layer successively formed on an upper surface of a pn junction positioned at the top of the plurality of pn junctions with respect to a lamination direction of the plurality of pn junctions.

13. The TE element of claim 12, wherein a ceramic material included in the ceramic layer is alumina.

14. The TE element of claim 1, further comprising a heat sink formed on a lower surface of a pn junction positioned at the bottom of the plurality of pn junctions with respect to a lamination direction of the plurality of pn junctions.

15. The TE element of claim 1, further comprising:
a power source connected to the first and second electrodes to form a circuit,
wherein the power source allows current to flow through the plurality of pn junctions so that heat absorbed from one side of the plurality of pn junctions is transferred along a lamination direction of the plurality of pn junctions.

16. The TE element of claim 1, further comprising:
a resistance device connected to the first and second electrodes to form a circuit,
wherein current flows through the plurality of pn junctions and the resistance device by heat absorbed from one side of the plurality of pn junctions.

17. The TE element of claim 1, wherein the insulating layers are formed of a ceramic material.
